(19) United States
(12) Patent Application Publication
(10) Pub. No.: US 2006/0181860 A1
(43) Pub. Date: Aug. 17, 2006

(54) Heat sink having directive heat elements

(76) Inventor: Ralph I. Larson, Acton, MA (US)

Correspondence Address: DALY, CROWLEY, MOFFORD & DURKEE, LLP, SUITE 301A, 354A TURNPIKE STREET, CANTON, MA, 02021-2714, US

(21) Appl. No.: 11/352,655

(22) Filed: Feb. 13, 2006

Related U.S. Application Data
(60) Provisional application No. 60/652,383, filed on Feb. 11, 2005.

(51) Int. Cl. H05K 7/20

(52) U.S. Cl. 361/720

(57) ABSTRACT

A heat sink includes a heat conducting substrate and a plurality of directive heat elements disposed within the substrate such that a first end of each of the plurality directive heat elements are adapted to be disposed proximate a heat generating device and a second end of each of the plurality of directive heat elements are spaced apart within the substrate to promote the transfer to heat from the heat generating device through the directive elements to an area of the heat conducting substrate which is larger than the area of the heat generating device. In this way, the heat sink transforms a high heat flux density existing at one end of the directive heat elements proximate a device being cooled to a low heat flux density at an opposite end of the directive heat elements.

### CROSS-REFERENCE TO RELATED APPLICATIONS

This application claims the benefit of provisional application No. 60/652,383 filed on Feb. 11, 2005 under 35 U.S.C. §119(e) and is incorporated herein by reference in its entirety.

### STATEMENTS REGARDING FEDERALLY SPONSORED RESEARCH

Not applicable.

### FIELD OF THE INVENTION

This invention relates generally to heat sinks and more particularly heat sinks having directive heat elements.

### BACKGROUND OF THE INVENTION

As is known in the art, certain classes of light emitting diodes (LEDs) are often provided from Group III-IV semiconductor materials such as Gallium-Arsenide (GaAs). Such LEDs can generate between 1-6 watts (W) of energy and consequently generate a substantial amount of heat. Thus, the LEDs are disposed on a heat sink.

Heat sinks are generally provided from thermally conductive materials such as copper (Cu) or aluminum (Al). Copper has a coefficient of thermal expansion which is relatively large compared with the coefficient of thermal expansion of many Group III-V semiconductor materials such as Gallium-Arsenide (GaAs). Due to the disparity between the coefficients of thermal expansion between the material from which the LED device is provided and the material from which the heat sink is provided, it is sometimes necessary to introduce a so-called “stress shield” between the LED device and the heat sink. Thus, to shield the Group III-V materials from direct contact with the heat sink materials (e.g. Cu), a stress relief plate (e.g. a plate comprised of silicon (Si), for example) is disposed between the LED device and the heat sink.

In embodiments in which the stress relief plate is comprised of a silicon (Si) substrate, the Si substrate can be provided having one or more connection points (e.g. one or more metalized regions) which allow one surface of the stress plate to be soldered (or otherwise attached) to the heat sink while the LED device is disposed on the opposing surface of the stress plate.

One problem with this approach is that the junctions between the LED device and the heat sink impede the efficient transfer of heat from the heat generating device (i.e. the LED device) to the heat sink. This limits the amount of power, and thus the amount of light, which the LED can generate without damaging the device. The inability to cool the LED structure results in practical devices being in the 1-5 W range.

### SUMMARY OF THE INVENTION

In accordance with the present invention, a heat sink includes a heat conducting substrate and a plurality of directive heat elements disposed within the substrate such that a first end of each of the plurality directive heat elements are adapted to be disposed proximate a heat generating device and a second end of each of the plurality of directive heat elements are spaced apart within the substrate to promote the transfer to heat from the heat generating device through the directive elements to an area of the heat conducting substrate which is larger than the area of the heat generating device.

With this particular arrangement, a heat sink which transforms a high heat flux density which exists at one end of the directive heat elements proximate a device being cooled to a low heat flux density at an opposite end of the directive heat elements is provided. By closely spacing the end of the directive heat elements proximate the heat generating device and increasing the spacing of the opposite ends the directive heat elements, the heat sink transfers heat from a relatively small area (i.e. the area proximate the heat generating device) of the heat sink to a relatively large area of the heat sink (i.e. an area of the heat sink distal from the heat generating device). By positioning the directive heat elements in the substrate such that they channel heat from the device sought to be cooled to a relatively large, heat sinking area in the substrate, the device can be cooled more rapidly and more efficiently. By providing the directive heat elements from a material having a relatively high heat transfer coefficient, the directive heat elements rapidly channel heat away from the heat generating device and toward a heat sink region having an area larger than the area of the heat source. By directing or channeling the heat from the device to be cooled toward a relatively large heat sinking area, the heat sink can dissipate relatively large amounts of heat and is capable of rapidly dissipating the heat generated by a heat generating device.

### BRIEF DESCRIPTION OF THE DRAWINGS

FIG. 1 is a cross-sectional view of a heat sink having directive heat elements disposed in a heat conducting substrate; and

FIG. 2 is an isometric view of a plurality of directive heat elements.

### DETAILED DESCRIPTION

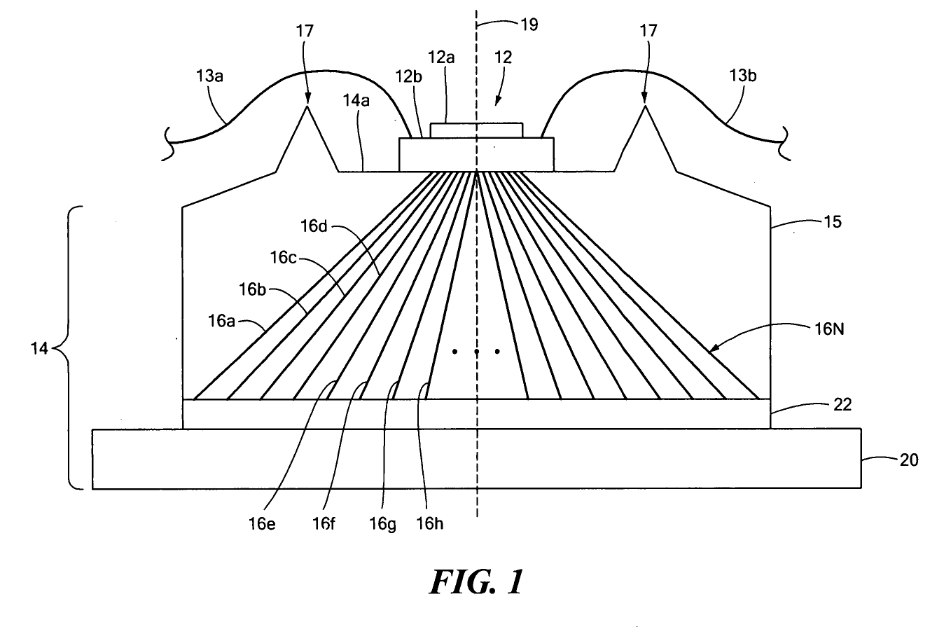

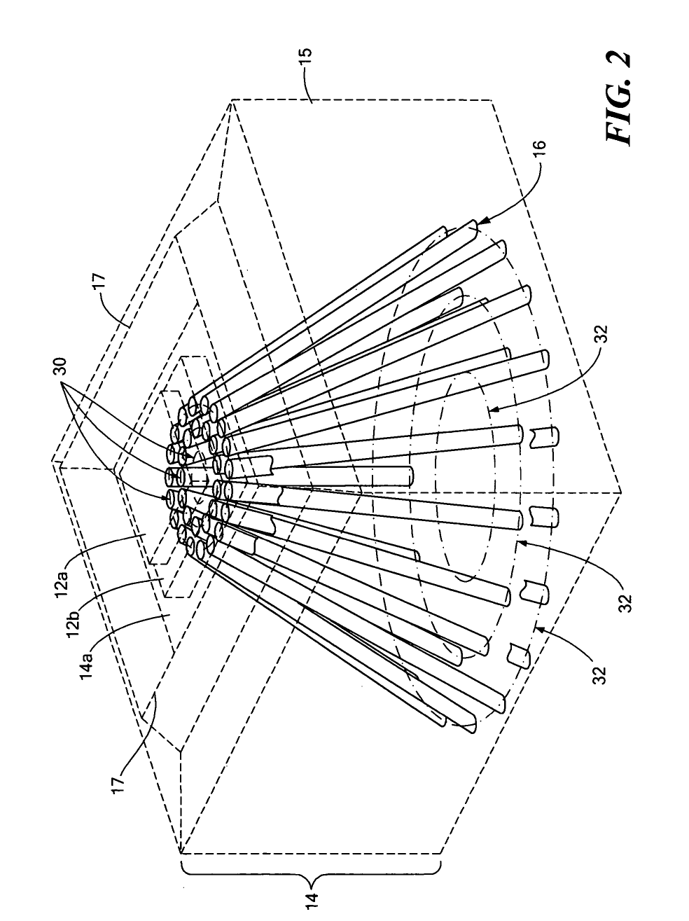

Referring now to FIGS. 1 and 2 in which like elements are provided having like reference designations, a heat generating device 12, is disposed on a first surface 14a of a heat sink 14 provided from a heat conducting substrate 15 (also referred to herein as a matrix 15) having a plurality of directive heat elements 16 (also referred to herein as heat pipes, fibers, strands or bundles) disposed therein. In this particular embodiment, the heat generating device 12 is shown as two stacked semiconductors 12a, 12b which can form an LED disposed in a recess region (more clearly visible in FIG. 2) defined by walls 17 projecting from a surface of the substrate 15.

The heat generating device 12 may be thermally coupled to the heatsink 14 via a solder connection (e.g. a semiconductor die soldered to the heat sink 14), epoxy or via any other connection technique or mechanism now known or unknown to those of ordinaru skill in the art. Electrical signal paths 13a, 13b may be used to couple device 12 to other circuits (not shown in FIG. 1) as is generally known. In the case where the device 12 corresponds to a semiconductor device, the signal paths 13, 13a may be provided as bond wires as is generally known. The particular manner in which the signal paths 13a, 13b are provided is selected in accordance with the particular type of device corresponding to the heat generating element 12 as well as the particular application in which the device 12 is being used.

The heat sink 14 is provided from a combination of here N thermal directive heat elements 16a-16N, generally denoted 16 and the thermally conductive substrate or matrix 15 through which the directive heat elements 16 are disposed. The directive heat elements 16 may be provided as solid state directive heat elements or as conventional heat pipes (e.g. copper tubes filled with a coolant such as water). In preferred embodiments, the directive heat elements are made from a material having a thermal conductivity higher than the thermal conductivity than the substrate 15. In one emodiment, the heat pipes 16 are made from graphite fibers. Those of ordocinary skill in the art will appreciate, of course, that other materials may also be used including but not limited to carbon, graphite diamond, Si Carbide, boron nitrude and aluminum nitride. The thermally conductive matrix 15 may, for example, be provided from a material such as copper. Other thermally conductive materials including but not limited to metals such as gold, silver or aluminum may also be used. Alternativley still, a gold-copper eutecctic braze material, or other moderate to higher melting point braze or solder material can also be used. In some embodiments, one criteria to use in selecting a particular material from which to provide the matrix 15 is that the melting point of the matrix material 15 should be higher than that of the solder (or other material) used to attach the device 12 (e.g. a semi-conductor die) to the matrix material and the matrix material should preferaby have a value of K greater than about 20 W/m-K.

Each of the one or more directive heat elements 16 are arranged in the heat sink matrix 15 in a particular pattern. Since the heat pipes 16 are provided from a material having a higher thermal conductivity than the material from which the substrate 15 is provided, the heat pipes 16 direct heat (or facilitate the conduction of heat) in a particular direction defined by the direction of the neat pipe 16. Thus, by concentrating one end of the heat pipes in a region proximate the heat generating device and expanding the spacing of the opposite end of the heat pipe throughout the substrate heat is efficiently and rapdily directed away from the heat generating device and dispersed throughout a large region in the substrate 15.

In one embodiment, the heat pipes 16 are provided from highly graphitized pitch based graphite fibers that exhibit anisotropic thermal conductivity in excess of that of the matrix material are preferred. Two sources of such fiber bundles or tows are Amoco BP, K1100 and Mitsubishi K13C2U. The K1100, for example is available in tow bundles of 2000 fibers and has a long fiber thermal conductivity of about K=1000 W/m-K. This compares favorably with copper which has a thermal conductivity of about K=345 W/m-K.

Alternatively, in some embodiments, it may be preferable to provide the heat pipes 16 from bundles of carbon fiber nanotube structures.

Each of the heat pipes 16a-16N may be provided as a single fiber structure (e.g. provided from a single strand fiber) or as a multi-fiber structure (e.g. a multi-strand fiber). In some embodiments, a combination of single and multi-strand fibers may be used. Significantly, the fibers are positioned in directions in which it is desirable to conduct or channel the heat.

In one embodiment, the heat pipes 16 are provided as graphite fibers which are arranged in a generally triangular (e.g. pyramidal) or cone shape with a tip of the cone disposed in the portion of the heat sink proximate the heat generating device 12 (e.g. a semiconductor device) which may, for example, be provided as an LED device. The base of the cone is disposed in the heat sink portion distal from the heat generating device. Care should be observed to concentrate the fibers 16 as tightly as can reasonably be achieved in the portion of the heat sink 14 proximate the heat generating device 12 so that the ends of the fibers 16 are exposed to or placed close to (or even in contact with) the heat generating device 12. In the case where the heat generating device is a semiconductor device, it may be desirable that the ends of the fibers 16 be exposed to or placed close to (or even in contact with) the die location. The ends of the fiber 16 distal from the heat generating device are preferably uniformly distributed over a larger contact area (e.g. corresponding to the base of the triangular or cone shape formed by the fibers 16). The fibers 16 may lie along a straight path or they may fan out as shown in FIG. 1. Alternatively still, the outer rings of fibers may be bent (e.g. curved) away from a center line 19 of the heat sink 14 to achieve more efficient spreading and dissipation of heat throughout the heat sink 14. While it is desirable for the fibers 16 to be continuous for best performance, it is not necessary, as long as the fibers are substantially aligned in the direction of desired heat flow.

By arranging the heat pipes 16 such that a high concentration of heat pipes 16 (per unit area) are disposed proximate the heat generating device 12 and a lower concentration of heat pipes 16 (per unit area) are disposed throughout the heat conducting matrix 15, the heat sink 14 functions as a heat flux transformer. That is to say, that the heat sink 14 accepts heat at high heat flux density and rejects heat at a lower heat flux density with lower temperature gradient than conventional isotropic heat conduction materials.

It should be noted that in a cone-like shape or configuration of heat pipes (e.g. a cone, a truncated cone, pyramid or truncated pyramid configuration) their exists a higher concentration of graphite strands per unit area in the tip of the cone (i.e. the portion of the cone proximate the heat generating device) than the base of the cone (i.e. the portion of the cone distal from the heat generating device). If the concentration of fibers is sufficiently high such that the coefficient of thermal expansion in the region of the heat sink proximate the semiconductor device is substantially the same as the coefficient of thermal expansion of the semiconductor device itself, then a stress relief plate between the heat generating device 12 and the heats sink surface 14a can be omitted. It should be noted that the effect of reduction of the bulk expansion coefficient is greater than would conventionally be expected from the percentage area of the two materials. This is because the modulus of elasticity of the graphite material is significantly higher than that of the matrix material. Thus, in the case where the heat generating device is a semiconductor device, this allows the semiconductor device to be disposed directly on the surface of the heat sink. 14

Thus, one advantage gained by including fibers 16 in the substrate 15 is that if the substrate 15 is provided having a relatively large concentration of fibers 16 near the device 12 itself, the device 12 can be connected directly to the substrate 15 (it should be appreciated that the substrate 15 may also sometimes be referred to as a slug or a heat sink block). This approach removes one or more thermal junctions which are typically present in conventional arrangements.

By removing one or more thermal junctions, the thermal conduction of the die itself can be improved (e.g. from ˜10 c/w to ˜5 c/w) which results in the die being subject to lower stress and thus which allows elimination of any intermediate material (e.g. any intermediate silicon Si material) to act as a stress relief plate. In some embodiments, however, it may not be desirable to entirely omit the stress relief plate, but the stress relief plate can be reduced in size and shape. For example, the stress relief plate could be made thinner. With a thinner relief plate, the temperature gradient across the stress relief plate element would be lower, so that the die could handle more power at the same temperature.

In one embodiment, the fibers are encased in a matrix material (e.g. like multiple wicks in a wax candle). The best known fibers of this type are made of carbon arranged in a graphite crystal structure. This is a hexagonal structure and the bonds between sheets are very weak. It is possible to roll up the sheets into tubes, called nanotubes. Carbon forms the presently most available and the more general name for these materials is “fullerenes.” It is now beginning to be recognized that other materials may also form these structures.

Generally the matrix materials are weaker structurally and isotropic (like the wax in a candle). It should be appreciated that a high thermal conductivity matrix that is also strong enough to hold the composite together is desired.

Thus, the diamond form of carbon, in monolithic form would be an alternative to this embodiment. This approach, however, is presently believed to be relatively expensive. Thus, due at least in part to cost considerations, the approach of using a diamond form of carbon is believed to be too expensive for some applications such as LED lighting applications.

The substrate 15, having the heating generating device 12 disposed thereon is disposed over a circuit board 20. In some embodiments, a thermal epoxy 22 can be disposed between a surface of the substrate 18 and a surface of the circuit board 20.

In one embodiment, circuit board 20 can be provided as the type manufactured by Heat Technology, Inc., Sterling Ma under U.S. Pat. Nos. 5,687,062 and 5,774,336 and identified by the name UltraTemp™ circuit boards. In this case, the circuit board 20 can be considered a part of the heat sink 14.

Referring now to FIG. 2, the heat generating device 12 and substrate 15 are shown in phantom to improve the clarity with which the directive heat elements 16 can be seen. As can be most clearly seen in FIG. 2, the directive heat elements 16 are disposed in a cone shape with a first end of the heat pipes disposed in a ring shape (identified by rings 30 in FIG. 2) and second end of the heat pipes disposed in a ring shape (identified by rings 32 in FIG. 2).

Although the directive heat elements are here shown arranged in a cone shaped pattern within the matrix 15, it should be appreciated that the directive heat elements 16 may be arranged in any pattern including but not limited to patterns having a rectangular block shape, a square block shape, a pyramidal shape, an egg-shape, a ball shape or even an irregular shape. Also, a mixture of shapes can be used. For example, the first end of the heat pipes 16 may be arranged in a rectangular pattern and the second ends of the heat pipes 16 may be arranged in a circular pattern. Those of ordinary skill in the art will appreciate how to select the particular geometry and shape of the directive heat elements considering a variety of factors including but not limited to the shape of the device being cooled, the shape of the substrate in which the directive heat elements are disposed, the geometry available for the heat sink on a particular circuit board.

It should be appreciated that the optional circuit board 20 has been omitted from FIG. 2, since in some applications the circuit board 20 is not properly a part of the heat sink 14. Also omitted from FIG. 2 is the thermal epoxy 22 which is also not properly a part of the heat sink in some applications.

Having described preferred embodiments of the invention, it will now become apparent to one of ordinary skill in the art that other embodiments incorporating their concepts may also be used. It is felt therefore that these embodiments should not be limited to disclosed embodiments but rather should be limited only by the spirit and scope of the appended claims.

All publications and references cited herein are expressly incorporated herein by reference in their entirety.

What is claimed is:

1. A heat sink for use with a semiconductor device, the heat sink comprising:
a heat sink matrix provided from a first material, said heat sink matrix having a first surface adapted to accept the semiconductor device; and
one or more directive heat elements disposed in said heat sink matrix, each of said one or more directive heat elements comprised of a material which is different from the first material with said heat pipes disposed in said heat sink matrix to promote the transfer of heat in a direction away from the first surface of said heat sink matrix in a manner such that said one or more directive heat elements transform a high heat flux density which exists at the first surface of said heat sink matrix to a low heat flux density at an opposite end of the directive heat elements.

2. The heat sink of claim 1 wherein said directive heat elements are provided as solid state heat pipes.

3. The heat sink of claim 2 wherein said directive heat elements are provided from one of nanotubes or fibers.

4. The heat sink of claim 1 wherein said directive heat elements are provided form one of:
one or more graphite fibers;
one or more carbon nanotubes; or
a carbon material arranged in a graphite crystal structure.

5. The heat sink of claim 1 wherein said substrate is provided from at least one of: copper, silver, aluminum, and gold-copper eutectic.

6. The heat sink of claim 1 wherein at least some of said fibers are provided as single-strand fibers.

7. The heat sink of claim 1 wherein at least some of said fibers are provided as multi-strand fibers.

8. The heat sink of claim 1 wherein said directive heat elements are disposed in one of: a cone-shape; a truncated cone-shape; a rectangular block shape; a square block shape; a pyramidal shape; or an irregular shape.

9. A heat sink comprising:
a heat conducting substrate having a first surface having a first region adapted to accept a heat generating device and a second opposing surface; and
a plurality of directive heat elements disposed within the substrate such that a first end of each of the plurality directive heat elements is adapted to be disposed proximate the first surface of said substrate and wherein said plurality of directive heat elements are disposed such that the first ends of said plurality of directive heat elements are disposed with a first density per unit area and a second end of each of the plurality of directive heat elements are disposed in said substrate with a second density per unit with the first and second densities per unit area selected to promote the transfer to heat from the heat generating device through the directive elements to an area of the heat conducting substrate which is larger than the area of the heat generating device.

10. The heat sink of claim 9 wherein said directive heat elements are provided as solid state heat pipes.

11. The heat sink of claim 9 wherein said directive heat elements are provided from one of nanotubes or fibers.

12. The heat sink of claim 9 wherein said directive heat elements are provided form one of:
one or more graphite fibers;
one or more carbon nanotubes; or
a carbon material arranged in a graphite crystal structure.

13. The heat sink of claim 9 wherein said substrate is provided from at least one of: copper, silver, aluminum, and gold-copper eutectic.

14. The heat sink of claim 9 wherein at least some of said fibers are provided as single-strand fibers.

15. The heat sink of claim 9 wherein at least some of said fibers are provided as multi-strand fibers.

16. The heat sink of claim 9 wherein said directive heat elements are disposed in one of: a cone-shape; a truncated cone-shape; a rectangular block shape; a square block shape; a pyramidal shape; or an irregular shape.
